(19) United States
(12) Patent Application Publication
(10) Pub. No.: US 2025/0389766 A1
(43) Pub. Date: Dec. 25, 2025

(54) DETECTION DEVICE, SEMICONDUCTOR CHIP, AND DETECTION METHOD

(71) Applicant: ROHM CO., LTD., Kyoto (JP)

(72) Inventors: Akira URYU, Kyoto (JP); Hiroyuki SHINKAI, Kyoto (JP)

(21) Appl. No.: 19/237,151

(22) Filed: Jun. 13, 2025

(30) Foreign Application Priority Data
Jun. 20, 2024 (JP) 2024-099635

(51) Int. Cl. G01R 31/28

(52) U.S. Cl. CPC G01R 31/2853

(57) ABSTRACT

A detection device includes: a detector configured to detect a resistance value of at least one wiring arranged along an outer edge of a semiconductor chip, wherein when the at least one wiring has no defect, the detector detects a first resistance value required for the at least one wiring having no defect, and when the at least one wiring has a defect, the detector detects a second resistance value larger than the first resistance value.

### CROSS REFERENCE TO RELATED APPLICATION

The present invention claims priority under 35 U.S.C. § 119 Japanese Patent Application No. 2024-099635, filed on Jun. 20, 2024, the entire contents of which are incorporated herein by reference.

### TECHNICAL FIELD

The present disclosure relates to a detection device, a semiconductor chip, and a detection method.

### BACKGROUND

The semiconductor device manufacturing process includes a dicing process in which integrated circuits (ICs) formed on a wafer are cut into individual semiconductor chips. In the dicing process, when the wafer is cut with a blade, defects such as minute cracks and chipping may occur in the semiconductor chips.

In the related art, there is known a semiconductor chip including pads connected to terminals, a voltage clamping part, and wirings provided along an outer periphery of the semiconductor chip and disposed between the voltage clamping part and the pads. In the related art, whether chipping occurs or not is detected depending on whether a terminal voltage generated at a terminal is a clamping voltage or not.

### BRIEF DESCRIPTION OF DRAWINGS

The accompanying drawings, which are incorporated in and constitute a part of the specification, illustrate embodiments of the present disclosure.

FIG. 1 is a block diagram of a system according to a first embodiment.

FIG. 2 is a schematic diagram of a semiconductor chip according to the first embodiment as viewed from above.

FIG. 3 is an enlarged perspective view of a region of a seal ring shown in FIG. 2.

FIG. 4 is a cross-sectional view of the seal ring taken along line A-A in FIG. 3.

FIG. 5 is an enlarged perspective view of a region of a wiring shown in FIG. 2.

FIG. 6 is a cross-sectional view of the wiring taken along line B-B in FIG. 5.

FIG. 7 is a schematic diagram of a portion of a semiconductor chip viewed from above, showing an example of a state in which a defect occurs in the semiconductor chip due to dicing.

FIG. 8 is a cross-sectional view of a portion of a wiring taken along line C-C in FIG. 7.

FIG. 9 is a cross-sectional view of a portion of a wiring according to a first modification.

FIG. 10 is a cross-sectional view of a portion of a wiring according to a second modification.

FIG. 11 is a perspective view of a portion of a wiring according to a third modification.

FIG. 12 is a schematic diagram of a semiconductor chip according to a fourth modification as viewed from above.

FIG. 13 is a schematic diagram of a semiconductor chip according to a second embodiment as viewed from above.

FIG. 14 is a block diagram of a detection circuit according to the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Summary

A summary of some exemplary embodiments of the present disclosure will be described. This summary is intended to provide a simplified description of some concepts of one or more embodiments to provide a basic understanding of the embodiments as a preface to the following detailed description, and is not intended to limit the scope of the invention or the disclosure. This summary is not a comprehensive overview of all conceivable embodiments and does not intend to specify essential components of the embodiments or define the scope of a part of all aspects of the embodiments. For the sake of convenience, “an embodiment” may be used to refer to one embodiment (example or modification) or multiple embodiments (examples or modifications) disclosed in the present disclosure.

A detection device according to an embodiment of the present disclosure includes a detector configured to detect a resistance value of a wiring arranged along an outer edge of a semiconductor chip. The detector is configured to detect a first resistance value required for a wiring having no defect when the wiring has no defect, and detect a second resistance value larger than the first resistance value when the wiring has a defect.

According to this configuration, presence or absence of the defect in the semiconductor chip can be determined based on the detected resistance value of the wiring, which makes it possible to easily detect defects in the semiconductor chip.

In an embodiment, the detection device may further include a determinator configured to determine a state of the semiconductor chip in accordance with a result of detecting the resistance value of the wiring obtained by the detector. The determinator may determine that the semiconductor chip has no defect when the detector detects the first resistance value, and may determine that the semiconductor chip has the defect when the detector detects the second resistance value.

In an embodiment, a plurality of wirings may be arranged on the semiconductor chip. The plurality of wirings may be laminated so as to be electrically insulated from each other. The detector may detect a resistance value of each of the plurality of wirings.

In an embodiment, a plurality of wirings separated from each other when viewed from above may be arranged on the semiconductor chip, and the detector may detect a resistance value of each of the plurality of wirings.

In an embodiment, the wiring may include a switch element provided inside a semiconductor substrate of the semiconductor chip and two conductive portions connected via the switch element. The detector may detect a resistance value of a range of the wiring including the two conductive portions when the switch element is turned on.

In an embodiment, the semiconductor chip may further include a first terminal, a second terminal, a first switch provided between one end of the wiring and the first terminal, and a second switch provided between the other end of the wiring and the second terminal. The detector may detect the resistance value of the wiring via the first terminal and the second terminal when both of the first switch and the second switch are turned on.

A semiconductor chip according to an embodiment includes a wiring arranged along an outer edge of a semiconductor chip. The wiring has a laminated structure including a plurality of uppermost layers, a plurality of connection portions, and a plurality of lowermost layers, each of which is made of a conductor. Two adjacent uppermost layers among the plurality of uppermost layers are connected to each other via the connection portions and the lowermost layers.

According to this configuration, the resistance value of the wiring can be detected, and presence or absence of the defect in the semiconductor chip can be determined based on the detected resistance value of the wiring, which makes it possible to easily detect the defect in the semiconductor chip.

In an embodiment, two adjacent uppermost layers may be connected to a common lowermost layer among the plurality of lowermost layers via different connection portions among the plurality of connection portions.

In an embodiment, the two adjacent uppermost layers may be connected to different lowermost layers among the plurality of lowermost layers via different connection portions among the plurality of connection portions, respectively. The two different lowermost layers connected to the two adjacent uppermost layers may be connected to each other via a connection element provided inside a semiconductor substrate of the semiconductor chip.

In an embodiment, the connection element may be a switch element.

In an embodiment, the semiconductor chip may further include a seal ring arranged along the outer edge of the semiconductor chip. The wiring may be arranged along an inner side of the seal ring.

In an embodiment, a plurality of wirings separated from each other when viewed from above may be arranged.

In an embodiment, the semiconductor chip may further include a first terminal, a second terminal, a first switch provided between one end of the wiring and the first terminal, and a second switch provided between the other end of the wiring and the second terminal.

A semiconductor chip according to an embodiment includes a wiring arranged along an outer edge of a semiconductor chip, and a detection circuit configured to detect, from the wiring, a signal indicating a resistance value of the wiring arranged along the outer edge of the semiconductor chip. The detection circuit is configured to detect, from the wiring, a first signal indicating a first resistance value required for a wiring having no defect when the wiring has no defect, and detect, from the wiring, a second signal indicating a second resistance value larger than the first resistance value when the wiring has a defect.

According to this configuration, presence or absence of the defect in the semiconductor chip can be determined based on the signal indicating the detected resistance value of the wiring, which makes it possible to easily detect the defect in the semiconductor chip.

In an embodiment, the detection circuit may include a defect signal generation circuit configured to generate a defect signal indicating that the semiconductor chip has the defect in response to the detection of the second signal.

In an embodiment, the detection circuit may further include a comparison circuit configured to compare the signal detected from the wiring with a reference voltage and generate a comparison signal indicating that the signal detected from the wiring is the second signal according to a result of the comparison. The signal detected from the wiring may be a voltage across both ends of the wiring when a reference current is supplied to the wiring. The reference voltage may be a voltage according to a voltage to be generated across both ends of the wiring when the reference current is supplied to the wiring when the wiring has no defect. The defect signal generation circuit may generate the defect signal in response to the comparison signal.

A detection method according to an embodiment includes detecting a resistance value of a wiring arranged along an outer edge of a semiconductor chip. The detecting the resistance value of the wiring includes detecting a first resistance value required for the wiring having no defect when the wiring has no defect, and detecting a second resistance value larger than the first resistance value when the wiring has a defect.

According to this configuration, presence or absence of the defect in the semiconductor chip can be determined based on the detected resistance value of the wiring, which makes it possible to easily detect the defect in the semiconductor chip.

In an embodiment, the detection method may further include determining a state of the semiconductor chip according to a result of detecting the resistance value of the wiring. The determining the state of the semiconductor chip may include determining that the semiconductor chip has no defect when the first resistance value is detected, and determining that the semiconductor chip has the defect when the second resistance value is detected.

In an embodiment, a plurality of wirings may be arranged on the semiconductor chip. The plurality of wirings may be laminated so as to be electrically insulated from each other. The detecting the resistance value of the wiring may include detecting the resistance value of each of the plurality of wirings.

In an embodiment, a plurality of wirings separated from each other when viewed from above may be arranged on the semiconductor chip. The detecting the resistance value of the wiring may include detecting the resistance value of each of the plurality of wirings.

In an embodiment, the wiring may include a switch element provided inside a semiconductor substrate of the semiconductor chip, and two conductive portions connected via the switch element. The detecting the resistance value of the wiring may include detecting a resistance value of a range of the wiring including the two conductive portions when the switch element is turned on.

In an embodiment, the semiconductor chip may further include a first terminal, a second terminal, a first switch provided between one end of the wiring and the first terminal, and a second switch provided between the other end of the wiring and the second terminal. The detecting the resistance value of the wiring may include turning on both of the first switch and the second switch and detecting the resistance value of the wiring via the first terminal and the second terminal.

### Embodiments

Exemplary embodiments will be described below with reference to the drawings. The same or equivalent components, members, and processes shown in each drawing are designated by the same reference numerals, and duplicate descriptions thereof are omitted as appropriate. Furthermore, the embodiments are not intended to limit the present disclosure, but are merely examples. All of the features and combinations thereof described in the embodiments are not necessarily essential to the present disclosure.

In the present disclosure, “a state where a member A is connected to a member B” includes not only a case where the member A and the member B are physically directly connected but also a case where the member A and the member B are indirectly connected via any other member that does not substantially affect an electrical connection state between the members A and B or does not impair functions and effects achieved by combinations of the members A and B.

Similarly, “a state where a member C is connected (provided) between a member A and a member B” includes not only a case where the member A and the member C or the member B and the member C are directly connected but also a case where the member A and the member C or the member B and the member C are indirectly connected via any other member that does not substantially affect an electrical connection state between the members A and C or the members B and C or does not impair functions and effects achieved by combinations of the members A and C or the members B and C, in addition to a case where the member A and the member C or the member B and the member C are directly connected.

In the present disclosure, symbols attached to electrical signals such as voltage signals and current signals, or circuit elements such as resistors, capacitors, and inductors represent voltage values, current values, or circuit constants (resistance values, capacitance values, inductances) thereof as necessary.

### First Embodiment

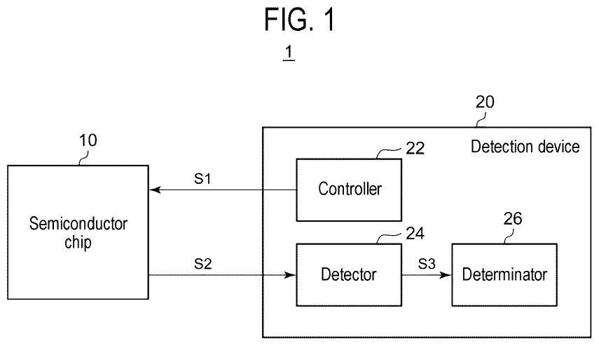

FIG. 1 is a block diagram of a system 1 according to a first embodiment of the present disclosure. The system 1 according to the present embodiment includes a semiconductor chip 10 and a detection device 20.

The semiconductor chip 10 is a chip in which functional circuits having various functions are provided on a semiconductor substrate made of a semiconductor such as silicon. The semiconductor chip 10 according to the present embodiment is provided with a wiring (described in detail later) for which presence or absence of a defect such as a crack or chipping in the semiconductor chip 10 is determined.

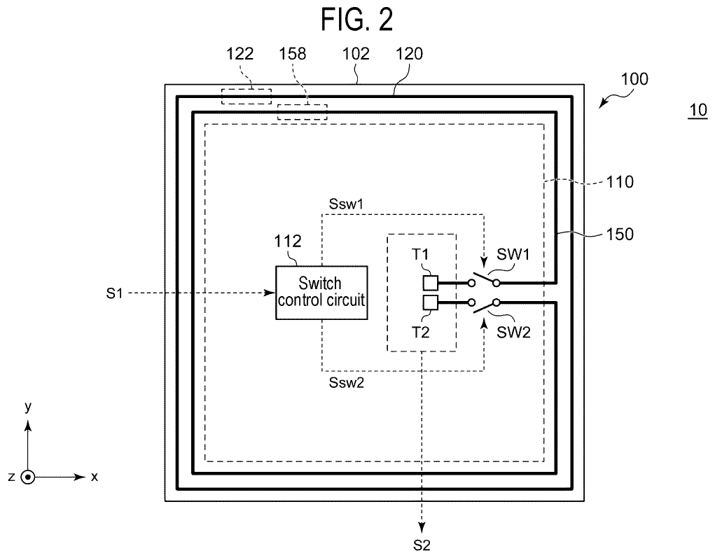

The detection device 20 according to the present disclosure detects a resistance value of the wiring arranged on the semiconductor chip 10. The detection device 20 according to the present embodiment includes a controller 22, a detector 24, and a determinator 26. Details of each functional part included in the detection device 20 according to the present embodiment will be described after describing a configuration of the semiconductor chip 10 with reference to FIG. 2. The detection device 20 may include a central processing unit (CPU), a random access memory (RAM), a read only memory (ROM), and the like, as necessary.

As described above, in a dicing process, when a semiconductor chip is separated from a wafer by a blade, a lateral force is applied to the semiconductor chip, which may cause defects. The detection device 20 according to the present embodiment can determine presence or absence of a defect in the semiconductor chip 10 based on a result of detecting the resistance value of the wiring arranged on the semiconductor chip 10.

FIG. 2 is a schematic diagram of the semiconductor chip 10 according to the first embodiment as viewed from above. The semiconductor chip 10 includes a semiconductor substrate 100, various functional circuits including a switch control circuit 112, a seal ring 120, a wiring 150, a switch SW1 (first switch), a switch SW2 (second switch), a terminal T1 (first terminal), and a terminal T2 (second terminal). The various functional circuits included in the semiconductor chip 10 are provided inside an active region 110 of the semiconductor chip 10, and are not provided outside the active region 110.

The semiconductor substrate 100 according to the present embodiment has a rectangular shape. In FIG. 2, a direction of one side of the semiconductor substrate 100 is defined as an x-axis, a direction of the other side of the semiconductor substrate 100 perpendicular to the x-axis is defined as a y-axis, and a direction perpendicular to the surface of the semiconductor substrate 100 perpendicular to the x-axis and the y-axis is defined as a z-axis. Also in other drawings, the directions of the x-axis, y-axis, and z-axis are the same as those in FIG. 2. In the present disclosure, a positive direction of the z-axis is defined as an upward direction, and a negative direction of the z-axis is defined as a downward direction.

The seal ring 120 is arranged along an outer edge of the semiconductor chip 10, specifically, along the outer edge 102 of the semiconductor substrate 100. The seal ring 120 according to present embodiment is located outside the active region 110 on the semiconductor substrate 100. This allows various functional circuits provided in the active region 110 to be protected by the seal ring. A distance between the seal ring 120 and the active region 110 may be, for example, about several um.

The wiring 150 is arranged along the outer edge of the semiconductor chip 10, specifically, along the outer edge 102 of the semiconductor substrate 100. The wiring 150 according to present embodiment is arranged on the semiconductor substrate 100 along the seal ring 120, outside the active region 110, and inside the seal ring 120. By arranging the wiring 150 inside the seal ring 120, the wiring 150 can be brought closer to the active region 110 than when the wiring 150 is arranged outside the seal ring 120, and a defect positioned close to the active region 110 can be detected.

The terminals T1 and T2 are provided inside the active region 110. The switches SW1 and SW2 are built into the semiconductor substrate 100 inside the active region 110. The switch SW1 is provided between one end of the wiring 150 and the terminal T1. The switch SW2 is provided between the other end of the wiring 150 and the terminal T2. Each of the switches SW1 and SW2 may be constituted by a switch element that is switched on and off in response to an input signal.

A signal S2 of the terminals T1 and T2 may be transmitted to the outside. The signal S2 may be, for example, a signal indicating a resistance value of the wiring 150. The signal S2 may be, for example, a voltage between the terminals T1 and T2 when a predetermined current is supplied to the wiring 150 from a current source (not shown).

In the present embodiment, an example will be described in which the terminals T1 and T2 are mainly used to detect the resistance value of the wiring 150. However, the terminals T1 and T2 may also be used as terminals of other functional circuits. When the terminals T1 and T2 are used for other functional circuits, the switches SW1 and SW2 are in an off state. By switching the switches SW1 and SW2 on and off in this manner, the terminals T1 and T2 can be used for both detection of the resistance value of the wiring 150 and realization of a function in the functional circuit. Therefore, according to the semiconductor chip 10 of the present embodiment, it is not necessary to provide an additional terminal dedicated to detecting the resistance value of the wiring 150.

The switch control circuit 112 controls operations (on/off operations) of the switches SW1 and SW2. The switch control circuit 112 may generate a signal Ssw1 for controlling the operation of the switch SW1 and a signal Ssw2 for controlling the operation of the switch SW2 in response to a signal S1 from the outside.

Returning to FIG. 1, functional parts of the detection device 20 according to the present embodiment will be described in detail.

The controller 22 generates the signal S1 for controlling the operation of the switch control circuit 112. The signal S1 may be transmitted to the switch control circuit 112 via the terminals T1 and T2, for example.

The detector 24 detects the resistance value of the wiring 150 arranged along the outer edge 102 of the semiconductor chip 10. The detector 24 according to the present embodiment detects the resistance value across both ends of the wiring 150 via the terminals T1 and T2 when both of the switches SW1 and SW2 are turned on. A signal S3 indicating the detection result is transmitted to the determinator 26. The detecting the resistance value of the wiring 150 may be measuring the resistance value of the wiring 150 by using various known measurement methods, or may be detecting a signal indicating the resistance value of the wiring 150. The detector 24 can receive the signal S2 from the terminals T1 and T2 as necessary.

The detector 24 detects a first resistance value required for a wiring 150 having no defect, and detects a second resistance value larger than the first resistance value when the wiring 150 has a defect. The second resistance value may be, for example, a resistance value larger than the first resistance value, or a resistance value larger than a resistance value obtained by adding a predetermined offset value to the first resistance value.

The determinator 26 determines a state of the semiconductor chip 10 according to a result of detecting the resistance value of the wiring 150 obtained by the detector 24. In the present embodiment, the determinator 26 determines the state of the semiconductor chip 10 based on a signal S3 indicating the result of detection obtained by the detector 24. Specifically, when the detector 24 detects the first resistance value, the determinator 26 determines that the semiconductor chip 10 has no defect, and when the detector 24 detects the second resistance value, the determinator 26 determines that the semiconductor chip 10 has a defect.

In a case where the wiring 150 has a defect, a portion of the wiring 150 is interrupted or narrowed, and the resistance value across both ends of the wiring 150 increases significantly. In a case where the second resistance value is detected, it can be inferred that the wiring 150 has a defect and that the semiconductor chip 10 also has a defect. Therefore, the determinator 26 can determine presence or absence of a defect in the semiconductor chip 10 based on the result of detection obtained by the detector 24.

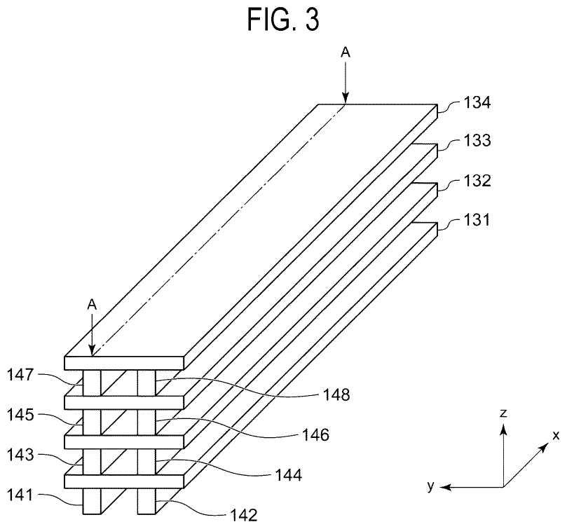

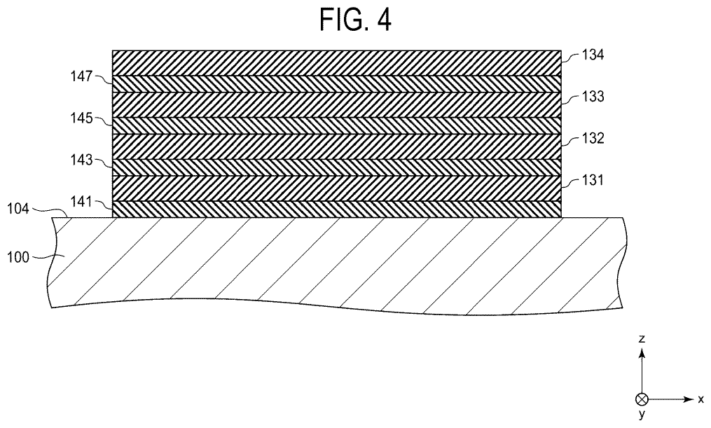

FIG. 3 is an enlarged perspective view of a region 122 of the seal ring 120 shown in FIG. 2. FIG. 4 is a cross-sectional view of the seal ring 120 taken along line A-A in FIG. 3.

The seal ring 120 according to the present embodiment includes a plurality of metal layers 131 to 134 and a plurality of vias 141 to 148. The plurality of metal layers 131 to 134 are laminated in this order from bottom. Each of the metal layers 131 to 134 may be made of, for example, aluminum. In the present embodiment, an example in which the metal layers 131 to 134 are four layers will be described. However, the number of layers of the metal layers may be three or less, or five or more.

Between the metal layers 131 to 134, the vias 143 to 148 are provided to connect the metal layers 131 to 134. Specifically, the vias 143 and 144 are provided between the metal layers 131 and 132, the vias 145 and 146 are provided between the metal layers 132 and 133, and the vias 147 and 148 are provided between the metal layers 133 and 134. In addition, the vias 141 and 142 are provided on a lower surface of the metal layer 131, and the metal layer 131 is connected to a surface 104 of the semiconductor substrate 100 through the vias 141 and 142.

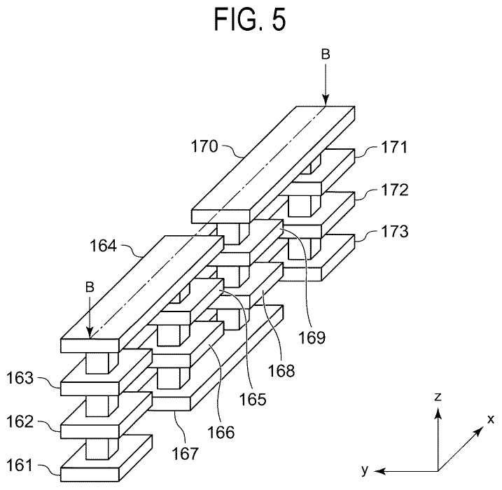

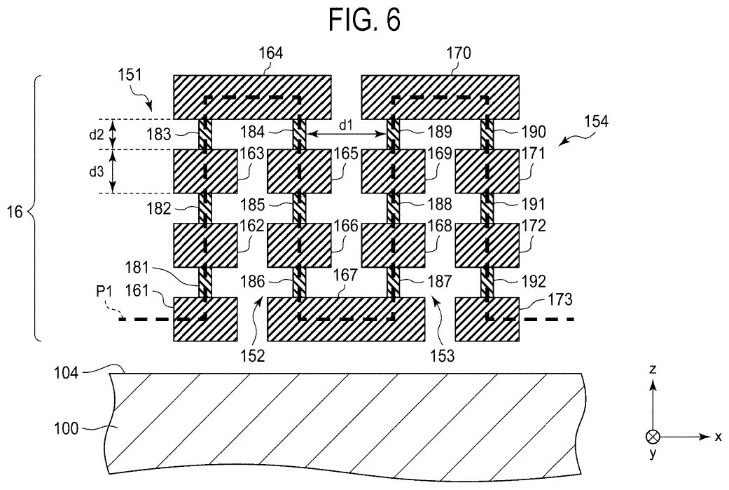

FIG. 5 is an enlarged perspective view of a region 158 of the wiring 150 shown in FIG. 2. FIG. 6 is a cross-sectional view of the wiring 150 taken along line B-B in FIG. 5.

The wiring 150 according to the present embodiment has a laminated structure 16 including a plurality of uppermost layers 164 and 170, a plurality of connection portions 151 to 154, and a plurality of lowermost layers 161, 167, and 173, each of which is made of a conductor. Two adjacent uppermost layers 164 and 170 among the plurality of uppermost layers 164 and 170 are connected to each other via the connection portions 152 and 153 and the lowermost layer 167. By using such a laminated structure 16 for the wiring 150, it is possible to improve accuracy of determining whether or not the semiconductor chip 10 has a defect.

Two adjacent uppermost layers 164 and 170 are connected to a common lowermost layer 167 among the plurality of lowermost layers 161, 167, and 173 via different connection portions 152 and 153 among the plurality of connection portions 151 to 154. By forming the wiring 150 in a zigzag shape in this manner, it is possible to further improve the accuracy of determining whether or not the semiconductor chip 10 has a defect.

Further, the uppermost layer 164 is connected to another lowermost layer 161 via the connection portion 151, and the uppermost layer 170 is connected to another lowermost layer 173 via the connection portion 154. The lowermost layers 161, 167, and 173 are each provided to be spaced apart above the surface 104 of the semiconductor substrate 100. The reason that the lowermost layers 161, 167, and 173 are spaced apart from the surface 104 of the semiconductor substrate 100 is that a contact layer (not shown) is provided on the surface 104 of the semiconductor substrate 100, and it is necessary to provide a distance corresponding to a thickness of the contact layer even in regions where the contact layer is not required. Although this distance may vary depending on the manufacturing process, it may be, for example, about 0.2 μm to 2 μm.

FIGS. 5 and 6 show parts of the lowermost layers 161 and 173. The lowermost layers 161 and 173 may have a same shape as that of the lowermost layer 167. Further, each of the lowermost layers 161 and 173 may be connected to an uppermost layer (not shown) via a connection portion.

The connection portion 151 includes a first intermediate layer 162, a second intermediate layer 163, and vias 181 to 183. The connection portion 152 includes a first intermediate layer 166, a second intermediate layer 165, and vias 184 to 186. The connection portion 153 includes a first intermediate layer 168, a second intermediate layer 169, and vias 187 to 189. The connection portion 154 includes a first intermediate layer 172, a second intermediate layer 171, and vias 190 to 192.

The lowermost layers 161, 167, and 173, the first intermediate layers 162, 166, 168, and 172, the second intermediate layers 163, 165, 169, and 171, and the uppermost layers 164 and 170 are laminated in this order from bottom. Each of these layers may be made of aluminum, for example.

The respective layers are connected by providing the vias 181 to 192 between the layers. For example, the vias 181, 186, 187, and 192 are provided between the lowermost layers 161, 167, and 173 and the first intermediate layers 162, 166, 168, and 172. Further, the vias 182, 185, 188, and 191 are provided between the first intermediate layers 162, 166, 168, and 172 and the second intermediate layers 163, 165, 169, and 171. In addition, the vias 183, 184, 189, and 190 are provided between the second intermediate layers 163, 165, 169, and 171 and the lowermost layers 164 and 170.

A distance d1 between adjacent vias in the x-axis direction may be about several μm, and may be, for example, about 0.2 μm to 2 μm, depending on the manufacturing process. This makes it possible to detect a defect having a size of about several μm. A length d2 of each via in the z-axis direction may be about several μm, and a thickness d3 of each layer may be about several μm.

By configuring the laminated structure 16 in the above manner, a connection path P1 is formed as indicated by a broken line in FIG. 6. In a case where a defect is generated in the semiconductor chip 10, for example, in a case where a break is generated in a portion of the wiring 150, the connection path P1 is interrupted. Even in a case where the wiring 150 is not broken, a portion of the connection path P1 may become narrow due to a defect. This causes the resistance value of the wiring 150 to increase significantly. For this reason, it is possible to determine the presence or absence of a defect in the semiconductor chip 10 by detecting the resistance value of the wiring 150.

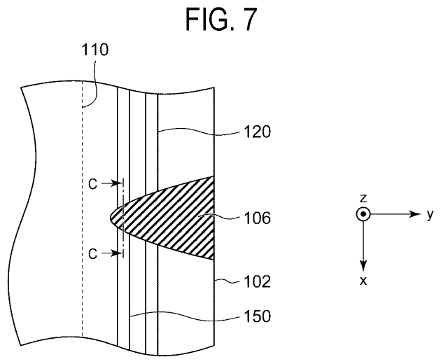

FIG. 7 is a schematic diagram of a portion of the semiconductor chip 10 as viewed from above, showing an example of a defect caused by dicing in the semiconductor chip 10. Chipping 106 shown in FIG. 7 has a size that extends from the outer edge 102 of the semiconductor chip 10 to the seal ring 120 and the wiring 150.

During dicing, the semiconductor substrate 100 is diced with a blade starting from a layer above the surface 104 (hereinafter, simply referred to as an “upper layer”). Therefore, damage caused by dicing occurs mainly in the upper layer compared to the layer existing below the surface 104 of the semiconductor substrate 100. At this time, chipping occurs from an upper end or a lower portion of the upper layer which comes in contact with the blade, resulting in the chipping 106 as shown in FIG. 7.

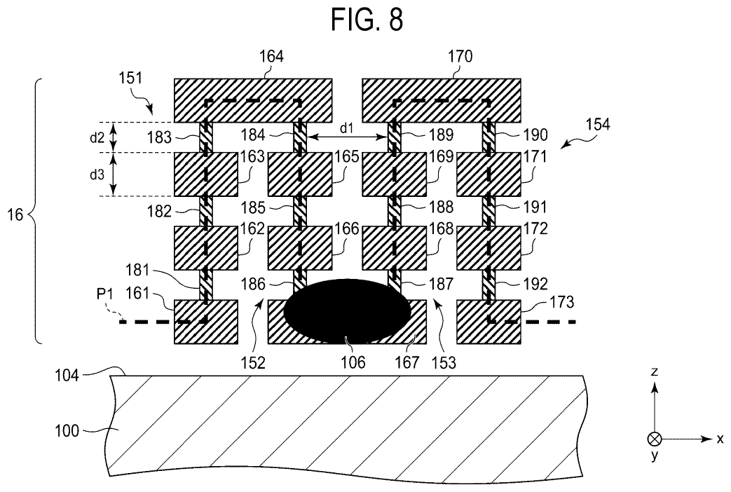

FIG. 8 is a cross-sectional view of the wiring 150 taken along line C-C in FIG. 7. As shown in FIG. 8, the chipping 106 causes damage to the lowermost layer 167 and the vias 186 and 187, and the connection path P1 is interrupted. As a result, the resistance across both ends of the wiring 150 increases significantly, which makes it possible to determine that the semiconductor chip 10 has a defect.

At this time, in a case where the chipping 106 has a length of distance d1 or more in the x-axis direction (i.e., a direction in which the wiring 150 extends), the chipping 106 will certainly cause damage to the wiring 150 and affect the resistance value of the wiring 150. Therefore, the detection device 20 according to the present embodiment can more certainly determine the presence or absence of the chipping 106 when the chipping 106 has a length of distance d1 or more in the x-axis direction. Accordingly, by setting the distance d1 to about several um, it becomes possible to detect chipping having a size of about several um.

FIG. 8 shows an example in which the lowermost layer 167 and the vias 186 and 187 are damaged. The layers above the lowermost layer 167 (such as the first intermediate layers 162, 166, 168, and 172, the second intermediate layers 163, 165, 169, and 171, and the uppermost layers 164 and 170) and the vias between those layers may also be damaged. Even in that case, the resistance value of the wiring 150 is affected, and chipping can be detected based on the resistance value. Therefore, in the laminated structure 16 according to the present embodiment, it is possible to detect chipping that occurs at any position.

The semiconductor chip 10 and the detection device 20 according to the present embodiment have been described above.

The detection device 20 according to the present embodiment includes the detector 24 configured to detect the resistance value of the wiring 150 arranged along the outer edge 102 of the semiconductor chip 10. When the wiring 150 has no defect, the detector 24 detects a first resistance value required for a wiring 150 having no defect, and when the wiring 150 has a defect, the detector 24 detects a second resistance value larger than the first resistance value.

According to this configuration, it is possible to determine presence or absence of a defect in the semiconductor chip 10 based on the detected resistance values (the first resistance value and the second resistance value). Therefore, it is possible to easily detect the defect in the semiconductor chip 10.

A wafer level chip size package (WLCSP) is a package in which the silicon substrate and an interlayer film are exposed and are easily damaged by external forces. During a dicing process, not limited to the WLCSP, a defect may be generated in the semiconductor chip when the semiconductor chip is separated by a blade. Even in a case where no defect is generated in the semiconductor chip during the dicing process, a defect may be generated in the semiconductor chip later due to certain causes. It is difficult to detect a defect having a size of about several um by visual inspection, and expensive equipment may be required to detect the defect with high accuracy.

The detection device 20 according to the present embodiment can determine presence or absence of a defect having a size of about several um by detecting a resistance value of the wiring 150 arranged along the outer edge 102 of the semiconductor chip 10. Therefore, the detection device 20 according to the present embodiment can detect the defect with ease and high accuracy and does not require visual inspection or the use of expensive inspection equipment, thereby reducing costs for defect detection.

In addition, in the visual inspection, it may be difficult to determine presence or absence of chipping based on an image, and some good products may be erroneously detected as defective products. In the visual inspection, for example, a foreign matter, a shadow, or a residue of an element such as a phase change material (PCM) may be erroneously detected as chipping. According to the detection device 20 of the present embodiment, the presence or absence of chipping can be electrically determined, which makes it possible to suppress erroneous detection that may occur in the visual inspection, and to improve a yield.

One conceivable method for estimating presence or absence of a defect in the semiconductor chip is to check whether the functional circuits of the semiconductor chip are operating properly. However, this method cannot exclude a possibility that a defect is generated in the semiconductor chip even in a case where the functional circuits are operating properly. According to the detection device 20 of the present embodiment, the presence or absence of a defect in the semiconductor chip 10 can be easily determined by detecting the resistance value of the wiring 150.

When the functional circuits of the semiconductor chip do not operate properly, it may not be possible to detect the presence or absence of a defect by visual inspection alone. In this case, an additional analysis such as a cross-section analysis is required. According to the detection device 20 of the present embodiment, the presence or absence of a defect in the semiconductor chip 10 can be easily determined without such an additional analysis.

The semiconductor chip 10 according to the present embodiment includes the wiring 150 arranged along the outer edge 102 of the semiconductor chip 10. The wiring 150 has the laminated structure 16 including the plurality of uppermost layers 164 and 170, the plurality of connection portions 151 to 154, and the plurality of lowermost layers 161, 167, and 173, each of which is made of a conductor. Two adjacent uppermost layers 164 and 170 of the plurality of uppermost layers 164 and 170 are connected to each other via the connection portions 152 and 153 and the lowermost layer 167.

According to this configuration, by using the laminated structure 16 for the wiring 150, it is possible to improve the accuracy of detecting a defect in the semiconductor chip 10. In particular, it is possible to improve accuracy of detecting chipping caused by dicing or the like from an end portion of the semiconductor chip 10. Further, according to this configuration, by measuring the resistance value of the wiring 150, it is possible to easily determine the presence or absence of a defect in the semiconductor chip 10.

### Modifications

Modifications of the first embodiment (modifications 1 to 5) are described below. The detection device according to each modification may have the same configuration as the detection device 20 according to the first embodiment, if necessary. Furthermore, the semiconductor chip according to each modification may have the same configuration as the semiconductor chip 10 according to the first embodiment, if necessary.

### First Modification

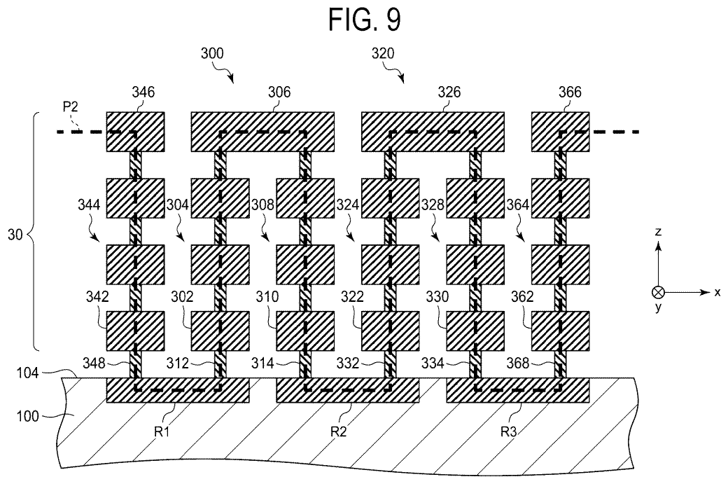

FIG. 9 is a cross-sectional view of a portion of a wiring according to a first modification. The wiring according to the first modification has a laminated structure 30 including a plurality of uppermost layers 306, 326, 346, and 366, a plurality of connection portions 304, 308, 324, 328, 344, and 364, and a plurality of lowermost layers 302, 310, 322, 330, 342, and 362, each of which is made of a conductor. Two adjacent uppermost layers 306 and 326 of the plurality of uppermost layers 306, 326, 346, and 366 are connected to each other via the connection portions 308 and 324 and the lowermost layers 310 and 322.

In the present embodiment, the two adjacent uppermost layers 306 and 326 are respectively connected to different lowermost layers 310 and 322 of the plurality of lowermost layers 302, 310, 322, 330, 342, and 362 via different connection portions 308 and 324 of the plurality of connection portions 304, 308, 324, 328, 344, and 364. The two different lowermost layers 310 and 322 connected to the two adjacent uppermost layers 306 and 326 are connected to each other via a connection element provided inside the semiconductor substrate 100 of the semiconductor chip.

In the first modification, resistors R1 to R3 are arranged as connection elements inside the semiconductor substrate 100. The resistors R1 to R3 are respectively connected to the two lowermost layers through vias. For example, the resistor R1 is connected to the lowermost layer 342 through a via 348 and to the lowermost layer 302 through a via 312. The resistor R2 is connected to the lowermost layer 310 through a via 314 and to the lowermost layer 322 through a via 332. The resistor R3 is connected to the lowermost layer 330 through a via 334 and to the lowermost layer 362 through a via 368. The uppermost layer 346 is connected to the lowermost layer 342 via a connection portion 344. The uppermost layer 366 is connected to the lowermost layer 362 via a connection portion 364.

Even when the wiring is configured as in this modification, presence or absence of a defect in the semiconductor chip can be determined by detecting the resistance value of the wiring. According to this modification, a portion of the wiring is included inside the semiconductor substrate 100, such that the presence or absence of a defect in the semiconductor substrate 100 can be determined with high accuracy.

### Second Modification

The wiring according to a second modification differs from the wiring according to the first modification in that the connection element provided inside the semiconductor substrate 100 is a switch element, specifically a metal oxide semiconductor (MOS) transistor.

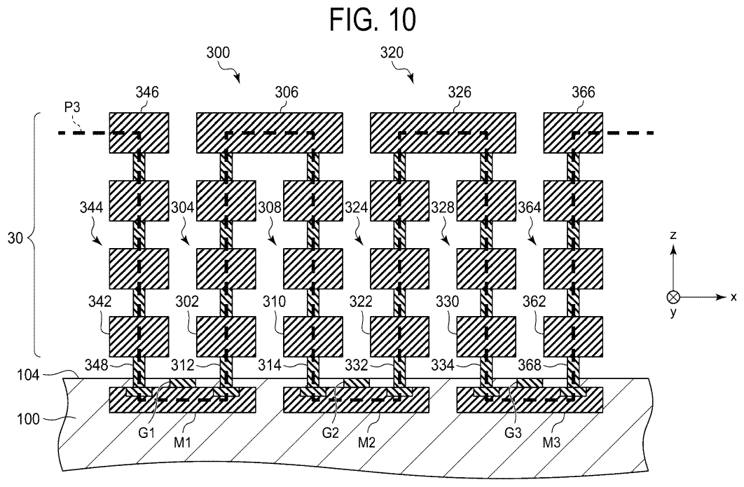

FIG. 10 is a cross-sectional view of a portion of the wiring according to the second modification. The wiring according to the second modification is configured to form a connection path P2. The wiring according to the second modification includes MOS transistors M1 to M3 as connection elements. The MOS transistors M1 to M3 are controlled to be turned on and off by inputting signals to gates G1 to G3, respectively. The number of MOS transistors is not limited to three, and may be two or less, or four or more.

Each of the MOS transistors M1 to M3 is provided between two vias. For example, the MOS transistor M1 is provided between the via 348 and the via 312. The MOS transistor M2 is provided between the via 314 and the via 332. Further, the MOS transistor M3 is provided between the via 334 and the via 368.

The vias 312 and 314, the lowermost layers 302 and 310, the connection portions 304 and 308, and the uppermost layer 306 constitute a conductive portion 300. Further, the vias 332 and 334, the lowermost layers 322 and 330, the connection portions 324 and 328, and the uppermost layer 326 constitute a conductive portion 320. The conductive portion 300 and the conductive portion 320 are connected to each other via the MOS transistor M2.

For example, when the MOS transistor M2 is turned on, the conductive portions 300 and 320 are electrically connected. The detector of the detection device according to the second modification detects a resistance value in a range including two conductive portions 300 and 320 at this time.

By controlling on/off operations of the MOS transistors M1 to M3, it is possible to control the range of the wiring that is electrically connected. By controlling the on/off operations of the MOS transistors M1 to M3, it is possible to electrically connect an entire connection path P3 of the wiring, cut off a portion of the connection path P3, or to electrically connect a portion of the connection path P3.

In a case where the wiring has no defect, it is assumed that when all of the MOS transistors M1 to M3 are turned on, the wiring is electrically connected from one end to the other end thereof. By turning on all of the MOS transistors M1 to M3 and measuring the resistance value across both ends of the wiring, it is possible to determine the presence or absence of a defect in the semiconductor chip 10.

It is assumed that the MOS transistor M1 is turned off and the MOS transistors M2 and M3 are turned on. In this case, the electrical connection of the wiring is cut off at the MOS transistor M1. In this case, by measuring a resistance value of a region between one end of the wiring and the MOS transistor M1, it is possible to determine whether or not there is a defect in that region. Further, by measuring a resistance value of a region between the other end of the wiring and the MOS transistor M1, it is possible to determine whether or not there is a defect in that region.

In this manner, with the wiring according to the second modification, the electrically connected range of the wiring can be changed by controlling the on/off operations of the MOS transistors M1 to M3. By detecting the resistance value of the changed electrically connected range, it becomes possible to determine a location of the defect with high accuracy.

### Third Modification

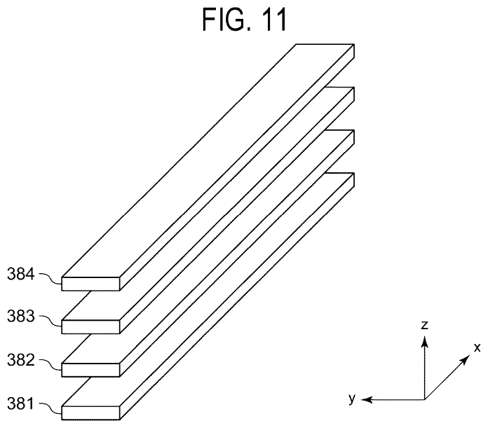

FIG. 11 is a perspective view of a portion of a wiring according to a third modification. In the third modification, a semiconductor chip has a plurality of wirings 381 to 384 arranged thereon. The plurality of wirings 381 to 384 are laminated so as to be electrically insulated from each other. For example, an insulating interlayer film (not shown) may be provided between two wirings among the wirings 381 to 384. While FIG. 11 shows an example in which the number of layers of the wirings is four, the number of layers of the wirings may be two, three, or five or more.

The detector included in the detection device according to the third modification detects a resistance value of each of the wirings 381 to 384. This makes it possible to determine the presence or absence of a defect in the semiconductor chip with high accuracy.

### Fourth Modification

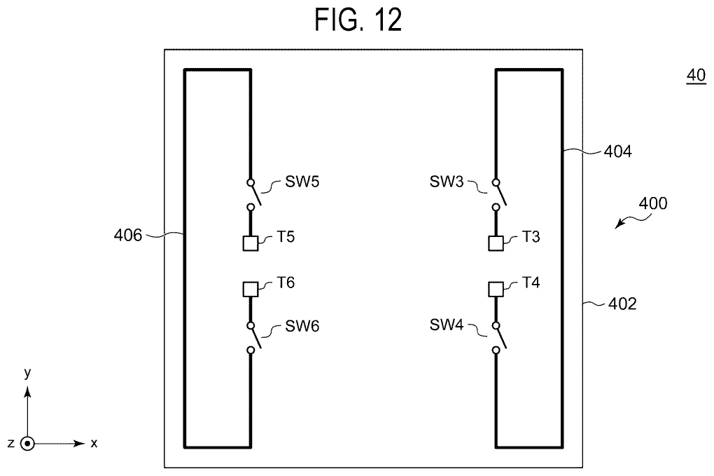

FIG. 12 is a schematic diagram of a semiconductor chip 40 according to a fourth modification as viewed from above. When viewed from above, the semiconductor chip according to the fourth modification includes a plurality of wirings 404 and 406 arranged thereon and separated from each other. In FIG. 12, the seal ring and the switch controller are omitted.

The wiring 404 is provided along an outer edge of the semiconductor chip 40 (mainly, a side on a right side of the outer edge 402 of a semiconductor substrate 400). One end of the wiring 404 is connected to a terminal T3 via a switch SW3, and the other end of the wiring 404 is connected to a terminal T4 via a switch SW4. The wiring 406 is provided along the outer edge of the semiconductor chip 40 (mainly, a side on a left side of the outer edge 402 of the semiconductor substrate 400). One end of the wiring 406 is connected to a terminal T5 via a switch SW5, and the other end of the wiring 406 is connected to a terminal T6 via a switch SW6.

The detector of the detection device according to the fourth modification detects a resistance value of each of the plurality of wirings 404 and 406. Specifically, the detector detects the resistance value of the wiring 404 when the switches SW3 and SW4 are turned on. This makes it possible to determine presence or absence of a defect mainly in the vicinity of a right side of the semiconductor chip 10. The detector also detects the resistance value of the wiring 406 when the switches SW5 and SW6 are turned on. This makes it possible to determine presence or absence of a defect mainly in the vicinity of a left side of the semiconductor chip 10. By providing the plurality of wirings 404 and 406 in this manner, when a defect is generated in the semiconductor chip 40, it becomes possible to identify a position of the defect.

Although FIG. 12 shows an example in which the wirings are provided mainly along a side parallel to the y-axis, the wirings may be provided mainly along a side parallel to the x-axis. This makes it possible to determine presence or absence of a defect in the vicinity of each side.

### Fifth Modification

In the first embodiment, there has been described an example in which the wiring 150 is arranged inside the seal ring 120. The present disclosure is not limited thereto. The wiring 150 may be arranged outside the seal ring 120. Alternatively, the wiring 150 may be arranged in place of the seal ring 120. As described above, the wiring 150 has a three-dimensional shape in the same manner as the seal ring 120 and has a function of protecting the active region 110 of the semiconductor chip 10 in the same manner as the seal ring 120.

### Second Embodiment

The second embodiment differs from the first embodiment in that a function of detecting a signal indicating a resistance value of the wiring and determining presence or absence of a defect in the semiconductor chip based on a result of the detection is integrated into the semiconductor chip.

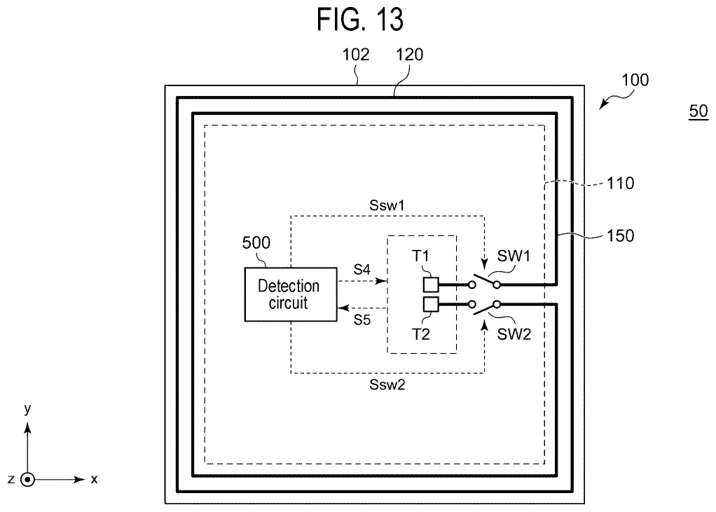

FIG. 13 is a schematic diagram of a semiconductor chip 50 according to the second embodiment as viewed from above. The semiconductor chip 50 according to the second embodiment includes a semiconductor substrate 100, various functional circuits including a detection circuit 500, a seal ring 120, a wiring 150, switches SW1 and SW2, and terminals T1 and T2.

The detection circuit 500 is configured to detect, from the wiring 150, a signal S5 indicating a resistance value of the wiring 150 arranged along an outer edge 102 of the semiconductor chip 50. When the wiring 150 has no defect, the detection circuit 500 detects, from the wiring 150, a first signal indicating a first resistance value required for the wiring 150 having no defect, and when the wiring 150 has a defect, the detection circuit 500 detects, from the wiring 150, a second signal corresponding to a second resistance value larger than the first resistance value. A relationship between the first resistance value and the second resistance value may be the same as that in the first embodiment.

The detection circuit 500 can generate signals Ssw1 and Ssw2 for controlling operations of the switches SW1 and SW2. Further, the detection circuit 500 can supply a signal S4 to the terminals T1 and T2 or receive a signal S5 from the terminals T1 and T2. In the present embodiment, the terminal T2 may be connected to the ground.

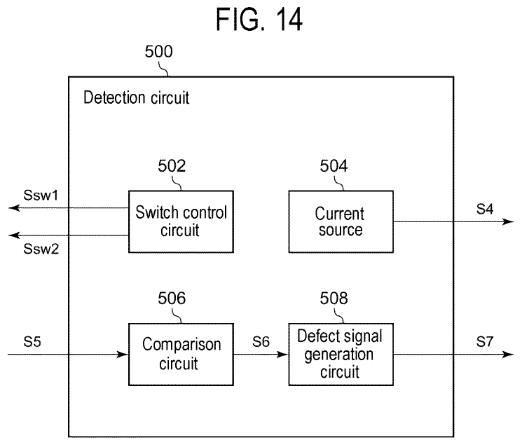

FIG. 14 is a block diagram of the detection circuit 500 according to the second embodiment. The detection circuit 500 according to the present embodiment includes a switch control circuit 502, a current source 504, a comparison circuit 506, and a defect signal generation circuit 508.

The switch control circuit 502 generates the signals Ssw1 and Ssw2 to control the operations of the switches SW1 and SW2. The switch control circuit 502 may turn on the switches SW1 and SW2 in a mode for determining presence or absence of a defect in the semiconductor chip 50 and may turn off the switches SW1 and SW2 in other modes.

When both of the switches SW1 and SW2 are turned on, the current source 504 supplies a predetermined reference current Iref as a signal S4 to the terminal T1. As a result, the reference current Iref is supplied to the wiring 150 in a direction from one end connected to the terminal T1 to the other end connected to the terminal T2. For example, in a case where the wiring 150 has no defect and the reference current Iref flows through the wiring 150, a voltage according to the reference current Iref and the first resistance value is generated across both ends of the wiring 150.

The comparison circuit 506 compares the signal S4 detected from the wiring 150 with a reference voltage Vref, and generates a comparison signal S6 according to a result of the comparison. Specifically, the comparison circuit 506 may receive the voltage across both ends of the wiring 150 when the reference current Iref is supplied to the wiring 150 as a signal S5 via the terminal T1 and may compare the signal S5 with the reference voltage Vref. The comparison circuit 506 may include a comparator configured to compare the signal S5 with the reference voltage Vref as necessary. An output signal of the comparator may be output to the outside of the semiconductor chip 50 as necessary.

In the case where the wiring 150 has no defect, the reference voltage Vref is a voltage corresponding to a voltage to be generated across both ends of the wiring 150 when the reference current Iref is supplied to the wiring 150. The reference voltage Vref may be, for example, a voltage obtained by adding (or subtracting) a predetermined offset voltage Voff to (or from) a voltage V1 to be generated across both ends of the wiring 150 when the wiring 150 has no defect.

The comparison circuit 506 may generate a comparison signal S6 indicating that the signal S5 detected from the wiring 150 is the second signal according to the comparison result. The reference voltage Vref may be set appropriately.

For example, the reference voltage Vref may be set to a voltage lower than the voltage V1 (hereinafter, also referred to as “reference voltage Vref1”). When the reference current Iref does not flow through the wiring 150, no voltage corresponding to the reference current Iref is generated across both ends of the wiring 150. When the signal S5 is lower than the reference voltage Vref1, the comparison circuit 506 may generate a comparison signal S6 indicating that the signal S5 is the second signal.

Further, the reference voltage Vref may be set to a voltage higher than the voltage V1 (hereinafter also referred to as “reference voltage Vref2”). When the wiring 150 has a defect to the extent that the wiring 150 is not disconnected, the resistance value of the wiring 150 becomes larger than the first resistance value. In this case, the reference current Iref flows. However, the voltage generated across both ends of the wiring 150 becomes higher than the voltage V1. When the signal S5 is higher than the reference voltage Vref2, the comparison circuit 506 may generate a comparison signal S6 indicating that the signal S5 is the second signal.

In response to detecting the second signal, the defect signal generation circuit 508 generates a defect signal S7 indicating that the semiconductor chip 50 has a defect. The defect signal generation circuit 508 according to the present embodiment generates a defect signal S7 in response to the comparison signal S6. This defect signal S7 may be transmitted to an external device. This allows a user to confirm that the semiconductor chip 50 has a defect.

The operation of the detection circuit 500 described above may be started when a predetermined functional circuit in the semiconductor chip 50 is activated. This makes it possible to determine whether or not the semiconductor chip 50 has a defect and then control the operation of the functional circuit.

### Supplementary Explanation

Although the embodiments of the present disclosure have been described by using specific terms, the description is merely an example to aid understanding and does not limit the scope of the present disclosure or the claims. The scope of the present disclosure is defined by the claims. In addition, not only the embodiments described above, but also embodiments, examples, and modifications not described herein are included in the scope of the present disclosure.

One or more elements of the first embodiment may be combined with one or more elements of the second embodiment. For example, one or more configurations of the first to fifth modifications (specifically, the configuration and layout of the wiring) may be applied to the semiconductor chip 50 according to the second embodiment.

### Supplementary Notes

The techniques disclosed in the present disclosure may be understood in one aspect as follows.

### Supplementary Note 1

A detection device, including:

a detector configured to detect a resistance value of at least one wiring arranged along an outer edge of a semiconductor chip,

wherein when the at least one wiring has no defect, the detector detects a first resistance value required for the at least one wiring having no defect, and when the at least one wiring has a defect, the detector detects a second resistance value larger than the first resistance value.

### Supplementary Note 2

The detection device of Supplementary Note 1, further including:

a determinator configured to determine a state of the semiconductor chip in accordance with a result of detecting the resistance value of the at least one wiring obtained by the detector,

wherein the determinator determines that the semiconductor chip has no defect when the detector detects the first resistance value and determines that the semiconductor chip has the defect when the detector detects the second resistance value.

### Supplementary Note 3

The detection device of Supplementary Note 1 or 2, wherein the at least one wiring includes a plurality of wirings arranged on the semiconductor chip,

wherein the plurality of wirings are laminated so as to be electrically insulated from each other, and

wherein the detector detects the resistance value of each of the plurality of wirings.

### Supplementary Note 4

The detection device of any one of Supplementary Notes 1 to 3, wherein the at least one wiring includes a plurality of wirings separated from each other when viewed from above and arranged on the semiconductor chip, and

wherein the detector detects the resistance value of each of the plurality of wirings.

### Supplementary Note 5

The detection device of any one of Supplementary Notes 1 to 4, wherein the at least one wiring includes a switch element provided inside a semiconductor substrate of the semiconductor chip and two conductive portions connected via the switch element, and

wherein the detector detects a resistance value of a range of the at least one wiring including the two conductive portions when the switch element is turned on.

### Supplementary Note 6

The detection device of any one of Supplementary Notes 1 to 5, wherein the semiconductor chip further includes a first terminal, a second terminal, a first switch provided between one end of the at least one wiring and the first terminal, and a second switch provided between the other end of the at least one wiring and the second terminal, and

wherein the detector detects the resistance value of the at least one wiring via the first terminal and the second terminal when both of the first switch and the second switch are turned on.

### Supplementary Note 7

A semiconductor chip, including:

at least one wiring arranged along an outer edge of the semiconductor chip,

wherein the at least one wiring has a laminated structure including a plurality of uppermost layers, a plurality of connection portions, and a plurality of lowermost layers, each of which is made of a conductor, and

wherein two adjacent uppermost layers among the plurality of uppermost layers are connected to each other via the connection portions and the lowermost layers.

### Supplementary Note 8

The semiconductor chip of Supplementary Note 7, wherein the two adjacent uppermost layers are connected to a common lowermost layer among the plurality of lowermost layers via different connection portions among the plurality of connection portions.

### Supplementary Note 9

The semiconductor chip of Supplementary Note 7 or 8, wherein the two adjacent uppermost layers are connected to different lowermost layers among the plurality of lowermost layers via different connection portions among the plurality of connection portions, respectively, and

wherein the two different lowermost layers connected to the two adjacent uppermost layers are connected to each other via a connection element provided inside a semiconductor substrate of the semiconductor chip.

### Supplementary Note 10

The semiconductor chip of Supplementary Note 9, wherein the connection element is a switch element.

### Supplementary Note 11

The semiconductor chip of any one of Supplementary Notes 7 to 10, further including:

a seal ring arranged along the outer edge,

wherein the at least one wiring is arranged along an inner side of the seal ring.

### Supplementary Note 12

The semiconductor chip of any one Supplementary Notes 7 to 11, wherein the at least one wiring includes a plurality of wirings arranged so as to be separated from each other when viewed from above.

### Supplementary Note 13

The semiconductor chip of any one of Supplementary Notes 7 to 12, further including:

a first terminal;

a second terminal;

a first switch provided between one end of the at least one wiring and the first terminal; and

a second switch provided between the other end of the at least one wiring and the second terminal.

### Supplementary Note 14

A semiconductor chip, including:

a wiring arranged along an outer edge of the semiconductor chip; and

a detection circuit configured to detect, from the wiring, a signal indicating a resistance value of the wiring arranged along the outer edge of the semiconductor chip,

wherein when the wiring has no defect, the detection circuit detects, from the wiring, a first signal indicating a first resistance value required for the wiring having no defect, and when the wiring has a defect, the detection circuit detects, from the wiring, a second signal indicating a second resistance value larger than the first resistance value.

### Supplementary Note 15

The semiconductor chip of Supplementary Note 14, wherein the detection circuit includes a defect signal generation circuit configured to generate a defect signal indicating that the semiconductor chip has the defect in response to detection of the second signal.

### Supplementary Note 16

The semiconductor chip of Supplementary Note 15, wherein the detection circuit further includes a comparison circuit configured to compare the signal detected from the wiring with a reference voltage and generate a comparison signal indicating that the signal detected from the wiring is the second signal according to a result of the comparison,

wherein the signal detected from the wiring is a voltage across both ends of the wiring when a reference current is supplied to the wiring,

wherein the reference voltage corresponds to a voltage to be generated across both ends of the wiring when the reference current is supplied to the wiring when the wiring has no defect, and

wherein the defect signal generation circuit generates the defect signal in response to the comparison signal.

### Supplementary Note 17

A detection method, including:

detecting a resistance value of at least one wiring arranged along an outer edge of a semiconductor chip,

wherein the detecting the resistance value of the at least one wiring includes detecting a first resistance value required for the at least one wiring having no defect when the at least one wiring has no defect and detecting a second resistance value larger than the first resistance value when the at least one wiring has a defect.

### Supplementary Note 18

The detection method of Supplementary Note 17, further including:

determining a state of the semiconductor chip according to a result of detecting the resistance value of the at least one wiring,

wherein the determining the state of the semiconductor chip includes determining that the semiconductor chip has no defect when the first resistance value is detected and determining that the semiconductor chip has the defect when the second resistance value is detected.

### Supplementary Note 19

The detection method of Supplementary Note 17 or 18, wherein the at least one wiring includes a plurality of wirings arranged on the semiconductor chip,

wherein the plurality of wirings are laminated so as to be electrically insulated from each other, and

wherein the detecting the resistance value of the at least one wiring includes detecting the resistance value of each of the plurality of wirings.

### Supplementary Note 20

The detection method of any one of Supplementary Notes 17 to 19, wherein the at least one wiring includes a plurality of wirings separated from each other when viewed from above and arranged on the semiconductor chip, and

wherein the detecting the resistance value of the at least one wiring includes detecting the resistance value of each of the plurality of wirings.

### Supplementary Note 21

The detection method of any one of Supplementary Notes 17 to 20, wherein the wiring includes a switch element provided inside a semiconductor substrate of the semiconductor chip, and two conductive portions connected via the switch element, and

wherein the detecting the resistance value of the at least one wiring includes detecting a resistance value of a range of the at least one wiring including the two conductive portions when the switch element is turned on.

### Supplementary Note 22

The detection method of any one of Supplementary Notes 17 to 21, wherein the semiconductor chip further includes a first terminal, a second terminal, a first switch provided between one end of the at least one wiring and the first terminal, and a second switch provided between the other end of the at least one wiring and the second terminal, and

wherein the detecting the resistance value of the at least one wiring includes turning on both of the first switch and the second switch and detecting the resistance value of the at least one wiring via the first terminal and the second terminal.

While certain embodiments have been described, these embodiments have been presented by way of example only and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A detection device, comprising:
a detector configured to detect a resistance value of at least one wiring arranged along an outer edge of a semiconductor chip,
wherein when the at least one wiring has no defect, the detector detects a first resistance value required for the at least one wiring having no defect, and when the at least one wiring has a defect, the detector detects a second resistance value larger than the first resistance value.

2. The detection device of claim 1, further comprising:
a determinator configured to determine a state of the semiconductor chip in accordance with a result of detecting the resistance value of the at least one wiring obtained by the detector,
wherein the determinator determines that the semiconductor chip has no defect when the detector detects the first resistance value and determines that the semiconductor chip has the defect when the detector detects the second resistance value.

3. The detection device of claim 1, wherein the at least one wiring includes a plurality of wirings arranged on the semiconductor chip,
wherein the plurality of wirings are laminated so as to be electrically insulated from each other, and
wherein the detector detects the resistance value of each of the plurality of wirings.

4. The detection device of claim 1, wherein the at least one wiring includes a plurality of wirings separated from each other when viewed from above and arranged on the semiconductor chip, and
wherein the detector detects the resistance value of each of the plurality of wirings.

5. The detection device of claim 1, wherein the at least one wiring includes a switch element provided inside a semiconductor substrate of the semiconductor chip and two conductive portions connected via the switch element, and
wherein the detector detects a resistance value of a range of the at least one wiring including the two conductive portions when the switch element is turned on.

6. The detection device of claim 1, wherein the semiconductor chip further includes a first terminal, a second terminal, a first switch provided between one end of the at least one wiring and the first terminal, and a second switch provided between the other end of the at least one wiring and the second terminal, and
wherein the detector detects the resistance value of the at least one wiring via the first terminal and the second terminal when both of the first switch and the second switch are turned on.

7. A semiconductor chip, comprising:
at least one wiring arranged along an outer edge of the semiconductor chip,
wherein the at least one wiring has a laminated structure including a plurality of uppermost layers, a plurality of connection portions, and a plurality of lowermost layers, each of which is made of a conductor, and
wherein two adjacent uppermost layers among the plurality of uppermost layers are connected to each other via the connection portions and the lowermost layers.

8. The semiconductor chip of claim 7, wherein the two adjacent uppermost layers are connected to a common lowermost layer among the plurality of lowermost layers via different connection portions among the plurality of connection portions.

9. The semiconductor chip of claim 7, wherein the two adjacent uppermost layers are connected to different lowermost layers among the plurality of lowermost layers via different connection portions among the plurality of connection portions, respectively, and
wherein the two different lowermost layers connected to the two adjacent uppermost layers are connected to each other via a connection element provided inside a semiconductor substrate of the semiconductor chip.

10. The semiconductor chip of claim 9, wherein the connection element is a switch element.

11. The semiconductor chip of claim 7, further comprising:
a seal ring arranged along the outer edge,
wherein the at least one wiring is arranged along an inner side of the seal ring.

12. The semiconductor chip of claim 7, wherein the at least one wiring includes a plurality of wirings arranged so as to be separated from each other when viewed from above.

13. The semiconductor chip of claim 7, further comprising:
a first terminal;
a second terminal;
a first switch provided between one end of the at least one wiring and the first terminal; and
a second switch provided between the other end of the at least one wiring and the second terminal.

14. A semiconductor chip, comprising:
a wiring arranged along an outer edge of the semiconductor chip; and
a detection circuit configured to detect, from the wiring, a signal indicating a resistance value of the wiring arranged along the outer edge of the semiconductor chip,
wherein when the wiring has no defect, the detection circuit detects, from the wiring, a first signal indicating a first resistance value required for the wiring having no defect, and when the wiring has a defect, the detection circuit detects, from the wiring, a second signal indicating a second resistance value larger than the first resistance value.

15. The semiconductor chip of claim 14, wherein the detection circuit includes a defect signal generation circuit configured to generate a defect signal indicating that the semiconductor chip has the defect in response to detection of the second signal.

16. The semiconductor chip of claim 15, wherein the detection circuit further includes a comparison circuit configured to compare the signal detected from the wiring with a reference voltage and generate a comparison signal indicating that the signal detected from the wiring is the second signal according to a result of the comparison,
wherein the signal detected from the wiring is a voltage across both ends of the wiring when a reference current is supplied to the wiring,
wherein the reference voltage corresponds to a voltage to be generated across both ends of the wiring when the reference current is supplied to the wiring when the wiring has no defect, and
wherein the defect signal generation circuit generates the defect signal in response to the comparison signal.
